(19) United States
(12) Patent Application Publication
(10) Pub. No.: US 2026/0142686 A1
(43) Pub. Date: May 21, 2026

(54) TRANSMIT/RECEIVE SWITCH ARCHITECTURE THAT ENABLES AUTOMATIC SWITCHING BETWEEN TRANSMIT AND RECEIVE PATHS

(71) Applicant: Raytheon Company, Tewksbury, MA (US)

(72) Inventors: Brian P. Helm, Murphy, TX (US); David D. Heston, Dallas, TX (US)

(21) Appl. No.: 18/955,709

(22) Filed: Nov. 21, 2024

(51) Int. Cl. H04B 1/44; H03F 3/19

(52) U.S. Cl. CPC H04B 1/44; H03F 3/19; H03F 2200/451

(57) ABSTRACT

An apparatus includes a transmit path configured to be coupled to a signal pathway. The apparatus also includes a receive path configured to be coupled to the signal pathway. The apparatus further includes a transmit/receive switch configured to selectively couple the receive path to the signal pathway. The transmit path is configured to receive and use a first bias voltage and to provide the first bias voltage to the transmit/receive switch. The first bias voltage is configured to control a state of the transmit/receive switch to thereby control whether the receive path is coupled to the signal pathway.

### TECHNICAL FIELD

This disclosure relates generally to switching devices. More specifically, this disclosure relates to a transmit/receive switch architecture that enables automatic switching between transmit and receive paths.

### BACKGROUND

A transmit/receive or “T/R” switch refers to a device that selectively connects an antenna to either a transmitter or a receiver. For example, a transmit/receive switch can electrically couple a transmitter to an antenna in one state, and the transmit/receive switch can electrically couple a receiver to the antenna in another state. This allows both the transmitter and the receiver to use the same antenna to transmit and receive electromagnetic signals at different times. Transmit/receive switches are common components in a range of systems that communicate wirelessly.

### SUMMARY

This disclosure relates to a transmit/receive switch architecture that enables automatic switching between transmit and receive paths.

In a first embodiment, an apparatus includes a transmit path configured to be coupled to a signal pathway. The apparatus also includes a receive path configured to be coupled to the signal pathway. The apparatus further includes a transmit/receive switch configured to selectively couple the receive path to the signal pathway. The transmit path is configured to receive and use a first bias voltage and to provide the first bias voltage to the transmit/receive switch. The first bias voltage is configured to control a state of the transmit/receive switch to thereby control whether the receive path is coupled to the signal pathway.

Any single one or any combination of the following features may be used with the first embodiment. The transmit path may include a radio frequency (RF) matching network configured to receive the first bias voltage and to provide the first bias voltage to another component of the transmit path and the transmit/receive switch. The RF matching network may be configured to form an open circuit when the first bias voltage is below a threshold voltage in order to electrically disconnect the transmit path from the signal pathway. The receive path may include at least one RF matching network configured to receive a second bias voltage and to provide the second bias voltage to another component of the receive path. A direct current (DC) blocking capacitor may be connected between the signal pathway and the transmit/receive switch. An inductor may be connected in parallel with the transmit/receive switch. A DC blocking capacitor may be connected between the receive path and the transmit/receive switch.

In a second embodiment, a system includes a transmit path, where the transmit path includes a transmit amplifier having an output configured to be electrically coupled to a first signal pathway and an input electrically coupled to a second signal pathway. The system also includes a receive path, where the receive path includes a receive amplifier having an input configured to be electrically coupled to the first signal pathway and an output electrically coupled to a third signal pathway. The system further includes an antenna electrically coupled to the first signal pathway. In addition, the system includes a transmit/receive switch configured to selectively couple the receive path to the first signal pathway. The transmit path is configured to receive a first bias voltage and to provide the first bias voltage to the transmit amplifier and to the transmit/receive switch. The first bias voltage is configured to control a state of the transmit/receive switch to thereby control whether the receive path is electrically coupled to the first signal pathway.

Any single one or any combination of the following features may be used with the second embodiment. The transmit path may include an RF matching network configured to receive the first bias voltage and to provide the first bias voltage to the transmit amplifier and the transmit/receive switch. The RF matching network may be configured to form an open circuit when the first bias voltage is below a threshold voltage in order to electrically disconnect the transmit amplifier from the first signal pathway. The receive path may include at least one RF matching network configured to receive a second bias voltage and to provide the second bias voltage to the receive amplifier. A DC blocking capacitor may be connected between the first signal pathway and the transmit/receive switch. An inductor may be connected in parallel with the transmit/receive switch. A DC blocking capacitor may be connected between the receive path and the transmit/receive switch.

In a third embodiment, a method includes providing a first value of a first bias voltage to a transmit amplifier and to a transmit/receive switch. The method also includes configuring the transmit/receive switch to electrically disconnect a receive amplifier from an antenna in response to the first bias voltage. The method further includes providing a second value of the first bias voltage to the transmit amplifier and to the transmit/receive switch in order to electrically disconnect the transmit amplifier from the antenna and turn off the transmit amplifier. In addition, the method includes providing a second bias voltage to the receive amplifier to turn on the receive amplifier.

Any single one or any combination of the following features may be used with the third embodiment. The transmit amplifier may be operated using the first bias voltage. The receive amplifier may be operated using the second bias voltage. A DC voltage may be blocked using a DC blocking capacitor coupled between the antenna and the transmit/receive switch. An inductor coupled in parallel with the transmit/receive switch may be operated. A DC voltage may be blocked using a DC blocking capacitor connected between the receive amplifier and the transmit/receive switch.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example system supporting the use of a transmit/receive switch according to this disclosure;

FIG. 2 illustrates a more specific example system supporting the use of a transmit/receive switch according to this disclosure;

FIG. 3 illustrates an example use case for a transmit/receive switch according to this disclosure; and

FIG. 4 illustrates an example method for using a transmit/receive switch according to this disclosure.

### DETAILED DESCRIPTION

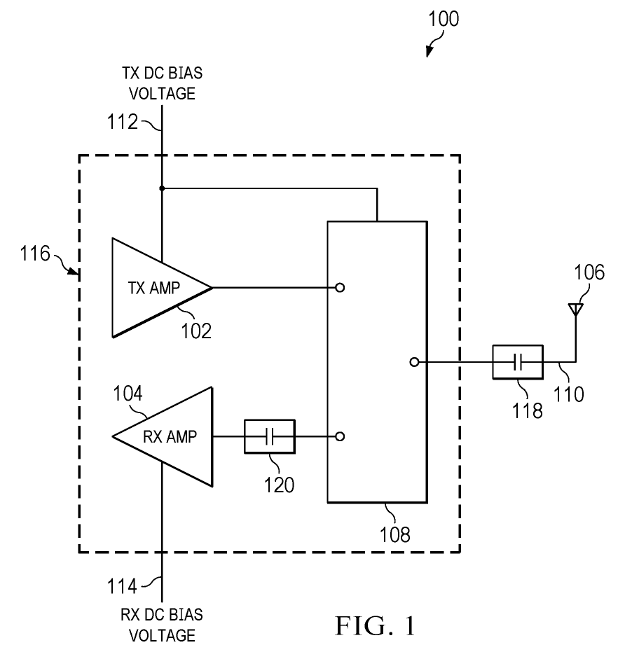

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, a transmit/receive or “T/R” switch refers to a device that selectively connects an antenna to either a transmitter or a receiver. For example, a transmit/receive switch can electrically couple a transmitter to an antenna in one state, and the transmit/receive switch can electrically couple a receiver to the antenna in another state. This allows both the transmitter and the receiver to use the same antenna to transmit and receive electromagnetic signals at different times. Transmit/receive switches are common components in a range of systems that communicate wirelessly. Unfortunately, the state of a transmit/receive switch is often controlled using a control signal that needs to be generated by a component and transported to the transmit/receive switch for use. This may be undesirable in various applications, such as mobile devices, satellite communications, radar systems, or other systems where space and weight are of concern. This may also be undesirable more generally in that it requires the use of a separate component to generate the control signal and the transport of the control signal to the transmit/receive switch, which can increase the cost of the overall system.

This disclosure provides various transmit/receive switch architectures that enables automatic switching. As described in more detail below, a transmit path and a receive path can be configured to be coupled to a signal pathway. The signal pathway could be coupled to an antenna. A transmit/receive switch can be configured to selectively couple the receive path to the signal pathway. The transmit path can be configured to receive and use a first bias voltage and to provide the first bias voltage to the transmit/receive switch. For example, the transmit path may include a radio frequency (RF) matching network configured to receive the first bias voltage and to provide the first bias voltage to another component of the transmit path (such as a transmit amplifier) and the transmit/receive switch. The RF matching network may also be configured to form an open circuit when the first bias voltage is below a threshold voltage in order to electrically disconnect the transmit path from the signal pathway. The first bias voltage can be configured to control a state of the transmit/receive switch to thereby control whether the receive path is coupled to the signal pathway. The receive path can be configured to receive a second bias voltage and to provide the second bias voltage to another component of the receive path (such as a receive amplifier).

In this way, the state of the transmit/receive switch may be controlled based on the first bias voltage (rather than by a separate control signal). For example, when the first bias voltage is high, the first bias voltage could power the transmit amplifier, and the first bias voltage can cause the transmit/receive switch to electrically disconnect the receive path from an antenna. When the first bias voltage is low, the transmit path could be electrically disconnected from the antenna, and the second bias voltage could power the receive amplifier. Thus, the transmit/receive switch can be controlled using one of the bias voltages, reducing or eliminating the need for an external component to generate a control signal and long signal lines for transporting the control signal. This can reduce the size and complexity of the overall system and can lower the insertion loss of the transmit/receive switch in both transmit and receive states. This can also allow a large voltage to be applied to the transmit/receive switch, reducing or eliminating the need for a charge pump to hold the transmit/receive switch in one state. Various other features can be supported, such as the use of one or more DC blocking capacitors or the use of an inductor that resonates with the transmit/receive switch (thereby equalizing a DC potential on the source and drain of the transmit/receive switch).

FIG. 1 illustrates an example system 100 supporting the use of a transmit/receive switch according to this disclosure. As shown in FIG. 1, the system 100 includes a transmit path having a transmit (TX) amplifier 102, a receive path having a receive (RX) amplifier 104, an antenna 106, and a transmit/receive switch 108. The transmit path generally represents circuitry and related electrical connections used to generate an outgoing electrical signal, such as one that contains data, which is provided to the antenna 106 during transmission. The transmit amplifier 102 can be used to amplify the outgoing electrical signal prior to reaching the antenna 106. The receive path generally represents circuitry and related electrical connections used to process an incoming electrical signal, such as one that contains data, as provided by the antenna 106 during reception. The receive amplifier 104 can be used to amplify the incoming electrical signal. Although not shown here, outgoing data or an electrical signal containing outgoing data can be provided to the transmit path from any suitable source, and incoming data or an electrical signal containing incoming data can be provided from the receive path to any suitable destination.

The transmit/receive switch 108 is used to selectively control which of the transmit path and the receive path is coupled to a signal pathway 110, which represents an electrical connection between the transmit/receive switch 108 and the antenna 106. For example, when the transmit/receive switch 108 is in one state, an output of the transmit amplifier 102 may be electrically coupled to the signal pathway 110 so that transmission via the antenna 106 can occur. When the transmit/receive switch 108 is in another state, an input of the receive amplifier 104 may be electrically coupled to the signal pathway 110 so that reception via the antenna 106 can occur.

In this example, a transmit DC bias voltage 112 can be provided to the transmit path and used (among other things) to power the transmit amplifier 102. Similarly, a receive DC bias voltage 114 can be provided to the receive path and used (among other things) to power the receive amplifier 104. Each DC bias voltage 112 and 114 can be generated by or otherwise received from any suitable source. As described in more detail below, the transmit DC bias voltage 112 can also be used to control the state of the transmit/receive switch 108. In other words, the transmit/receive switch 108 does not need to be controlled using a separate control signal and can instead be controlled using one of the DC bias voltages already being provided to the system 100.

One or more DC blocking capacitors may optionally be used in the system 100. For example, a DC blocking capacitor 118 may be coupled between the transmit/receive switch 108 and the signal pathway 110. Also or alternatively, a DC blocking capacitor 120 may be coupled between the transmit/receive switch 108 and the receive path, such as between the transmit/receive switch 108 and the receive amplifier 104. Each DC blocking capacitor 118-120 can be used to block a DC current that might otherwise interfere with the operation of the system 100. Each DC blocking capacitor 118-120 represents any suitable capacitive structure providing any suitable capacitance.

In some embodiments, various components shown in FIG. 1 may be implemented using an integrated circuit (IC) 116. In this example, for instance, the transmit amplifier 102, receive amplifier 104, and transmit/receive switch 108 can be integrated into the integrated circuit 116. In some embodiments, the integrated circuit 116 may represent a monolithic microwave integrated circuit (MMIC).

Each of the components shown in FIG. 1 may be implemented in any suitable manner using any suitable device(s). For example, in some embodiments, the transmit amplifier 102 may represent an operational amplifier. The transmit amplifier 102 may receive any suitable transmit DC bias voltage 112, such as a DC bias voltage between 0V and 24V. Also, in some embodiments, the receive amplifier 104 may represent an operational amplifier. The receive amplifier 104 may receive any suitable receive DC bias voltage 114, such as a DC bias voltage between 0V and 24V. Example embodiments of the transmit/receive switch 108 are described below. As described below, when the transmit DC bias voltage 112 is high (such as 24V) and the receive DC bias voltage 114 is low (such as 0V), this can cause the receive amplifier 104 to be electrically disconnected from the antenna 106, allowing the transmit amplifier 102 to provide a signal to the antenna 106 during transmission. When the transmit DC bias voltage 112 is low (such as 0V) and the receive DC bias voltage 114 is high (such as 24V), this can cause the transmit amplifier 102 to be electrically disconnected from the antenna 106, allowing the receive amplifier 104 to receive a signal from the antenna 106 during transmission. In this way, the transmit/receive switch 108 generally operates as an alternating connection between the transmit amplifier 102 and the receive amplifier 104 to the antenna 106.

Although FIG. 1 illustrates one example of a system 100 supporting the use of a transmit/receive switch, various changes may be made to FIG. 1. For example, various components in FIG. 1 may be combined, further subdivided, replicated, omitted, or rearranged and additional components may be added according to particular needs.

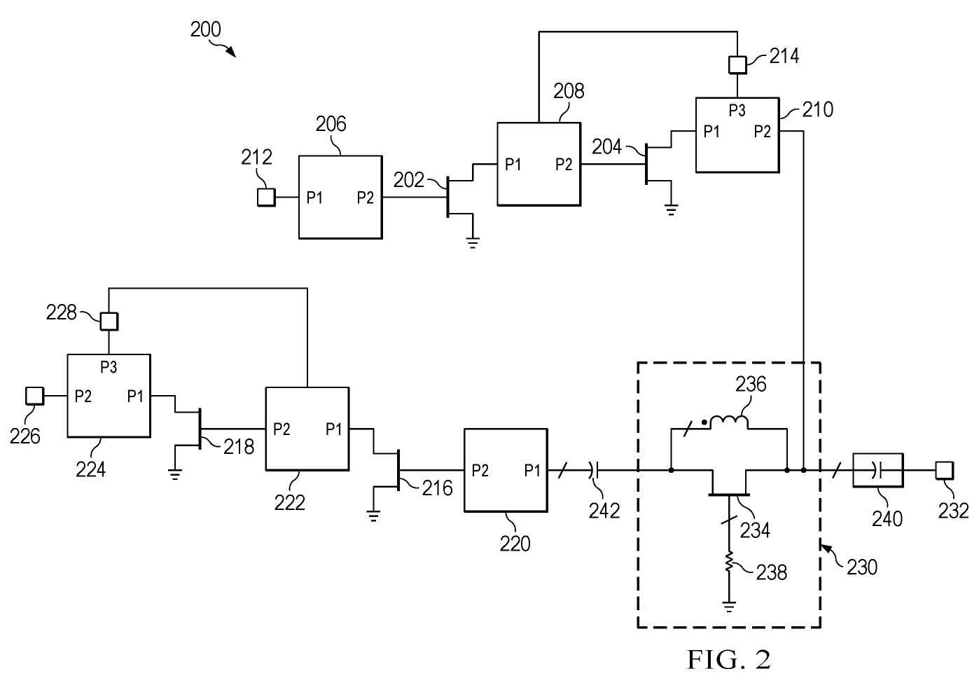

FIG. 2 illustrates a more specific example system 200 supporting the use of a transmit/receive switch according to this disclosure. More particularly, the system 200 represents a specific implementation of the system 100 shown in FIG. 1 and described above.

As shown in FIG. 2, the system 200 includes a transmit path having transistors 202-204 and radio frequency (RF) matching networks 206-210. Each transistor 202-204 represents any suitable transistor device, such as a field effect transistor. Each RF matching network 206-210 represents any suitable structure configured to match impedances in the transmit path. The RF matching network 206 is coupled to a signal pathway 212, which represents a pathway through which an electrical signal (such as one containing data) to be transmitted is received. The RF matching networks 208, 210 are coupled to a transmit DC bias voltage input 214, which can receive a transmit DC bias voltage (such as a voltage between 0V and 24V). The transmit path here implements a transmit amplifier that can be used to amplify an outgoing electrical signal.

The system 200 also includes a receive path having transistors 216-218 and RF matching networks 220-224. Each transistor 216-218 represents any suitable transistor device, such as a field effect transistor. Each RF matching network 220-224 represents any suitable structure configured to match impedances in the receive path. The RF matching network 224 is coupled to a signal pathway 226, which represents a pathway through which an electrical signal (such as one containing data) that has been received can be provided. The RF matching networks 222, 224 are also coupled to a receive DC bias voltage input 228, which can receive a receive DC bias voltage (such as a voltage between 0V and 24V). The receive path here implements a receive amplifier that can be used to amplify an incoming electrical signal.

In some embodiments, at least the RF matching network 210 can be designed to appear as an open circuit at a port P2 of the RF matching network 210 when the transmit DC bias voltage input 214 that is received is below a threshold voltage. Example approaches for implementing such an RF matching network 210 are provided in U.S. Patent No. 4,637,073 and U.S. Patent Publication No. 2012/0309327 (both of which are hereby incorporated by reference in their entirety).

A transmit/receive switch 230 can be used to selective couple the receive path to a signal pathway 232, which could represent an electrical connection to an antenna. In this example, the transmit/receive switch 230 is implemented using a transistor 234, optionally an inductor 236 coupled in parallel with the transistor 234, and a resistor 238. The transistor 234 represents any suitable transistor device, such as a field effect transistor. The inductor 236 represents any suitable inductive structure providing any suitable inductance. The resistor 238 can be used to couple a gate of the transistor 234 to ground. The resistor 238 represents any suitable resistive structure providing any suitable resistance, such as a resistance of about 10kΩ.

One or more DC blocking capacitors may optionally be used in the system 200. For example, a DC blocking capacitor 240 may be coupled between the transmit/receive switch 230 and the signal pathway 232. Also or alternatively, a DC blocking capacitor 242 may be coupled between the transmit/receive switch 230 and the receive path. Each DC blocking capacitor 240-242 can be used to block a DC current that might otherwise interfere with the operation of the system 200. Each DC blocking capacitor 240-242 represents any suitable capacitive structure providing any suitable capacitance.

During operation, in order to transmit, the transmit DC bias voltage input 214 can receive a high transmit DC bias voltage (such as about 24V), and the receive DC bias voltage input 228 can receive a low receive DC bias voltage (such as about 0V). This can create a large negative gate-to-source voltage across the transistor 234, which can place the transmit/receive switch 230 in a state that electrically disconnects the receive path from the signal pathway 232. As a result, the transmit path can be electrically connected to the signal pathway 232 and can provide an electrical signal during transmission. The high transmit DC bias voltage input 214 can therefore be used to both (i) power one or more components of the transmit path and (ii) control the transmit/receive switch 230 to electrically disconnect the receive path from the signal pathway 232 and connect the transmit path to signal pathway 232.

In order to receive, the transmit DC bias voltage input 214 can receive a low transmit DC bias voltage (such as about 0V), and the receive DC bias voltage input 228 can receive a high receive DC bias voltage (such as about 24V). The low transmit DC bias voltage also creates a zero value gate-to-source voltage across the transistor 234, which can place the transmit/receive switch 230 in a state that electrically connects the receive path to the signal pathway 232. Moreover, the low transmit DC bias voltage can cause the RF matching network 210 to appear as an open circuit at the port P2 of the RF matching network 210, thereby electrically disconnecting the transmit path from the signal pathway 232. As a result, the receive path can be electrically connected to the signal pathway 232 and can receive an electrical signal during reception. The low transmit DC bias voltage can therefore be used to control the transmit/receive switch 230 to electrically disconnect the transmit path from the signal pathway 232, and the high receive DC bias voltage input 228 can be used to power one or more components of the receive path.

The presence of the inductor 236 in parallel with the transistor 234 can create a resonance between the inductor 236 and the transistor 234. Among other things, this can help to equalize the DC potential on both the source and the drain of the transistor 234. Note, however, that use of the inductor 236 is optional. The presence of the DC blocking capacitor 240 and/or the DC blocking capacitor 242 can prevent a DC current from impacting operation of the system 200. Note, however, that use of the DC blocking capacitor 240 and/or the DC blocking capacitor 242 is optional.

Although FIG. 2 illustrates a more specific example of a system 200 supporting the use of a transmit/receive switch, various changes may be made to FIG. 2. For example, various components in FIG. 2 may be combined, further subdivided, replicated, omitted, or rearranged and additional components may be added according to particular needs. Also, while specific types of circuit components and circuit components with specific values are shown here and described above, other circuit components that perform the same or similar functions could be used here.

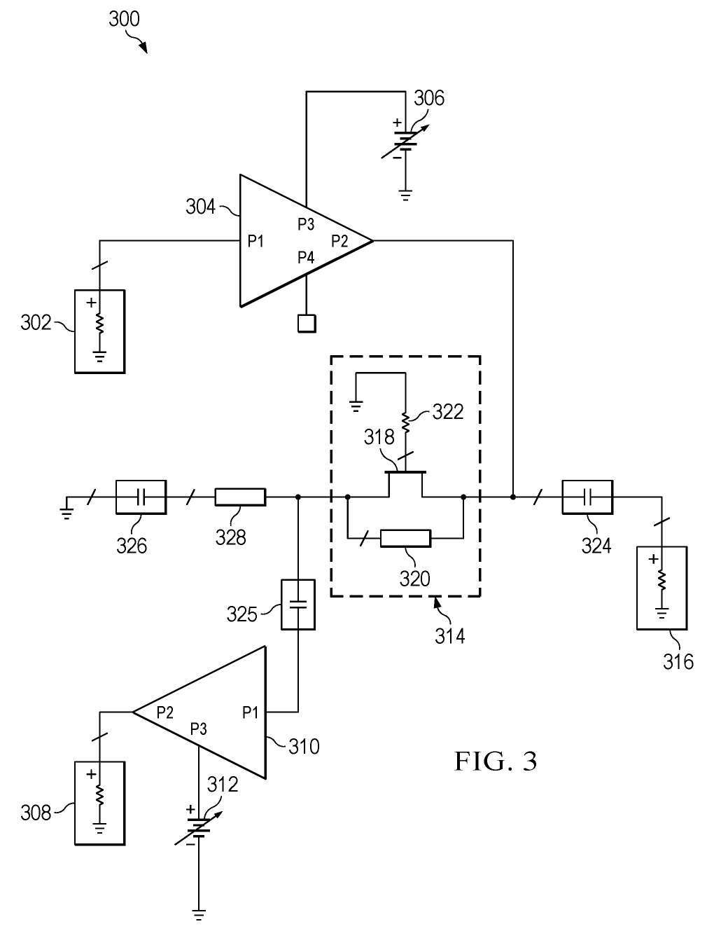

FIG. 3 illustrates an example use case for a transmit/receive switch according to this disclosure. More specifically, FIG. 3 illustrates an example circuit 300 that can implement a transmit/receive switch for use with Ka-band amplifiers. Various components of the circuit 300 are similar to corresponding components of the system 200 in FIG. 2.

As shown in FIG. 3, the circuit 300 includes a transmit path having a resistor 302 (which represents an impedance associated with a signal pathway), a transmit amplifier 304, and a variable DC voltage source 306. In some cases, the resistor 302 may represent an impedance of about 50Ω, the transmit amplifier 304 may represent a high-power amplifier (HPA), and the variable DC voltage source 306 may provide between 0V and 24V. The circuit 300 also includes a receive path having a resistor 308 (which represents an impedance associated with another signal pathway), a receive amplifier 310, and a variable DC voltage source 312. In some cases, the resistor 308 may represent an impedance of about 50Ω, the receive amplifier 310 may represent a low-noise amplifier (LNA), and the variable DC voltage source 312 may provide between 0V and 24V.

A transmit/receive switch 314 can be used to selectively couple the receive path to a resistor 316, which may represent an impedance of about 50Ω or other value associated with yet another signal pathway. The transmit/receive switch 314 includes a transistor 318, and an inductor 320 may be coupled in parallel with the transistor 318 to support resonance with the transistor 318. The inductor 320 can be tuned for Ka-band resonance with the transistor 318. A gate of the transistor 318 can be coupled to a resistor 322 (such as a resistor of about 10kΩ), and the resistor 322 can be coupled to ground. One or more DC blocking capacitors 324-326 may be included in the circuit 300, and a shunt inductor 328 may be coupled to the transmit/receive switch 314. The shunt inductor 328 can provide a Ka-band shunt inductance. Note, however, that the position of the shunt inductor 328 may vary, such as when the shunt inductor 328 forms part of an input matching network for the receive amplifier 310.

Although FIG. 3 illustrates one example use case for a transmit/receive switch, various changes may be made to FIG. 3. For example, various components in FIG. 3 may be combined, further subdivided, replicated, omitted, or rearranged and additional components may be added according to particular needs. Also, while specific types of circuit components and circuit components with specific values are shown here and described above, other circuit components that perform the same or similar functions could be used here. In addition, the specific use case described here is an example only.

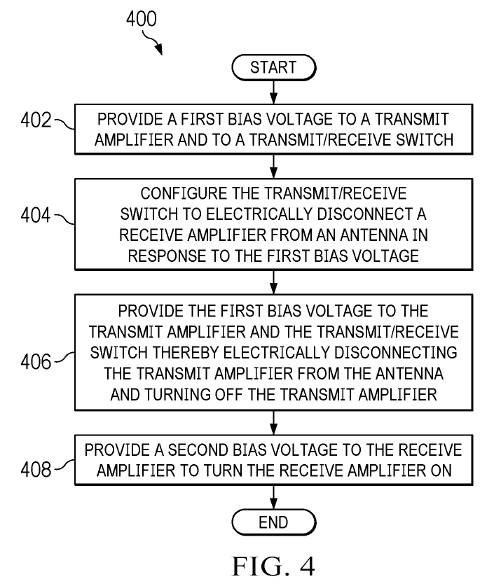

FIG. 4 illustrates an example method 400 for using a transmit/receive switch according to this disclosure. For ease of explanation, the method 400 is described as being performed using the system 200 of FIG. 2. However, the method 400 may be performed using any other suitable system, such as the system 100 of FIG. 1.

As shown in FIG. 4, a first value of a first bias voltage is provided to a transmit amplifier and to a transmit/receive switch at step 402. This may include, for example, providing a 24V or other high transmit DC bias voltage received at the transmit DC bias voltage input 214 to the circuit elements in the transmit path and to the transmit/receive switch 230. The transmit/receive switch electrically disconnects a receive path from an antenna (or a signal pathway to the antenna) in response to the first bias voltage at step 404. This may include, for example, forming a large negative gate-to-source voltage across the transistor 234 from the applied transmit DC bias voltage. This opens the transistor 234 and disconnects the receive path from the signal pathway 232.

A second value of the first bias voltage is provided to the transmit amplifier and to the transmit/receive switch at step 406. This may include, for example, changing the transmit DC bias voltage from 24V or other high bias voltage to 0V or other low bias voltage. This change in bias automatically disconnects the transmit amplifier from the antenna, configures the transmit/receive switch 230 to electrically connect the receive amplifier to the antenna, and turns off the transmit amplifier. A second bias voltage is provided to the receive amplifier at step 408. This may include, for example, providing a 24V or other high receive DC bias voltage received at the receive DC bias voltage input 228 to the circuit elements in the receive path, thereby turning on the receive amplifier.

Although FIG. 4 illustrates one example of a method 400 for using a transmit/receive switch, various changes may be made to FIG. 4. For example, while shown as a series of steps, various steps in FIG. 4 could overlap, occur in parallel, occur in a different order, or occur multiple times (including zero times). As a particular example, the transmit/receive switch may repeatedly switch back and forth to support repeating instances of transmissions and receptions.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a transmit path configured to be coupled to a signal pathway;
a receive path configured to be coupled to the signal pathway; and
a transmit/receive switch configured to selectively couple the receive path to the signal pathway;
wherein the transmit path is configured to receive and use a first bias voltage and to provide the first bias voltage to the transmit/receive switch; and
wherein the first bias voltage is configured to control a state of the transmit/receive switch to thereby control whether the receive path is coupled to the signal pathway.

2. The apparatus of claim 1, wherein the transmit path comprises a radio frequency (RF) matching network configured to receive the first bias voltage and to provide the first bias voltage to another component of the transmit path and the transmit/receive switch.

3. The apparatus of claim 2, wherein the RF matching network is further configured to form an open circuit when the first bias voltage is below a threshold voltage in order to electrically disconnect the transmit path from the signal pathway.

4. The apparatus of claim 1, wherein the receive path comprises at least one radio frequency (RF) matching network configured to receive a second bias voltage and to provide the second bias voltage to another component of the receive path.

5. The apparatus of claim 1, further comprising:
a direct current (DC) blocking capacitor connected between the signal pathway and the transmit/receive switch.

6. The apparatus of claim 1, further comprising:
an inductor connected in parallel with the transmit/receive switch.

7. The apparatus of claim 1, further comprising:
a direct current (DC) blocking capacitor connected between the receive path and the transmit/receive switch.

8. A system comprising:
a transmit path comprising a transmit amplifier having an output configured to be electrically coupled to a first signal pathway and an input electrically coupled to a second signal pathway;
a receive path comprising a receive amplifier having an input configured to be electrically coupled to the first signal pathway and an output electrically coupled to a third signal pathway;
an antenna electrically coupled to the first signal pathway; and
a transmit/receive switch configured to selectively couple the receive path to the first signal pathway;
wherein the transmit path is configured to receive a first bias voltage and to provide the first bias voltage to the transmit amplifier and to the transmit/receive switch; and
wherein the first bias voltage is configured to control a state of the transmit/receive switch to thereby control whether the receive path is electrically coupled to the first signal pathway.

9. The system of claim 8, wherein the transmit path further comprises a radio frequency (RF) matching network configured to receive the first bias voltage and to provide the first bias voltage to the transmit amplifier and the transmit/receive switch.

10. The system of claim 9, wherein the RF matching network is further configured to form an open circuit when the first bias voltage is below a threshold voltage in order to electrically disconnect the transmit amplifier from the first signal pathway.

11. The system of claim 8, wherein the receive path further comprises at least one radio frequency (RF) matching network configured to receive a second bias voltage and to provide the second bias voltage to the receive amplifier.

12. The system of claim 8, further comprising:
a direct current (DC) blocking capacitor connected between the first signal pathway and the transmit/receive switch.

13. The system of claim 8, further comprising:
an inductor connected in parallel with the transmit/receive switch.

14. The system of claim 8, further comprising:
a direct current (DC) blocking capacitor connected between the receive path and the transmit/receive switch.

15. A method comprising:
providing a first value of a first bias voltage to a transmit amplifier and to a transmit/receive switch;
configuring the transmit/receive switch to electrically disconnect a receive amplifier from an antenna in response to the first bias voltage;
providing a second value of the first bias voltage to the transmit amplifier and to the transmit/receive switch in order to electrically disconnect the transmit amplifier from the antenna and turn off the transmit amplifier; and
providing a second bias voltage to the receive amplifier to turn on the receive amplifier.

16. The method of claim 15, further comprising:
operating the transmit amplifier using the first bias voltage.

17. The method of claim 15, further comprising:
operating the receive amplifier using the second bias voltage.

18. The method of claim 15, further comprising:
blocking a direct current (DC) voltage using a DC blocking capacitor coupled between the antenna and the transmit/receive switch.

19. The method of claim 15, further comprising:
operating an inductor coupled in parallel with the transmit/receive switch.

20. The method of claim 15, further comprising:
blocking a direct current (DC) voltage using a DC blocking capacitor connected between the receive amplifier and the transmit/receive switch.
